(19) United States
(12) Patent Application Publication
(10) Pub. No.: US 2011/0189615 A1
(43) Pub. Date: Aug. 4, 2011

(54) SEMICONDUCTOR PROCESSING METHOD OF MANUFACTURING MOS TRANSISTOR

(76) Inventors: Tsung-Yu Hou, Chiayi County (TW); Tai-Heng Yu, Tainan City (TW); Chien-Wei Su, Tainan County (TW); Wen-Yi Teng, Kaohsiung City (TW)

(21) Appl. No.: 12/696,056

(22) Filed: Jan. 29, 2010

(51) Int. Cl. G03F 7/20

(52) U.S. Cl. 430/313; 430/319

(57) ABSTRACT

A method of manufacturing MOS transistor includes providing a substrate having a gate formed thereon; forming a hard mask layer on the substrate, performing an acid treatment to a surface of the hard mask layer, forming a photoresist layer on the hard mask layer after performing the acid treatment, performing a photolithography process to pattern the photoresist layer and the hard mask layer, performing an etching process to form recesses in the substrate, and performing a SEG method to form epitaxial layers respectively in the recesses.

### BACKGROUND OF THE INVENTION

1. Field of the Invention

The present invention relates to a semiconductor processing method, and more particularly, to a semiconductor processing method of manufacturing MOS transistor having strained silicon channel.

2. Description of the Prior Art

As semiconductor processes advance to 40-nm node and beyond, and with the progress of device miniaturization, enhancing carrier mobility and driving current of the MOS transistor has become an important issue. In order to improve the speed of the MOS transistor, the strained-silicon technique has been developed and is taken as a main solution to improve the performance of the MOS transistor.

One approach of the strained-silicon technique is applied with the selective epitaxial growth (SEG) method which involves forming an epitaxial layer, such as a SiGe layer, on a single-crystalline silicon substrate. Because the lattice constant of the epitaxial SiGe layer is larger than that of the silicon, such characteristic is employed to cause alteration to the band structure of the silicon in the channel region of the substrate. Accordingly, the carrier mobility and the speed performance of the MOS transistor are improved.

Please refer to FIGS. 1-3, which are schematic drawings illustrating a conventional method for manufacturing MOS transistor utilizing the SEG method. As shown in FIG. 1, a substrate 100 such as a silicon substrate is provided, and a plurality of shallow trench isolations (STIs) 102 is formed in the substrate 100. Then, a gate 110 is formed on the substrate 100 and followed by performing an ion implantation to form lightly-doped drains (LDDs) 112 in the substrate 100 at two sides of the gate 110. Next, a spacer 114 is formed on a sidewall of the gate 110, and followed by forming a hard mask layer on the substrate 100. Preferably, the hard mask layer is a silicon nitride (SiN) hard mask layer 120 that is able to prevent the STI 102, which comprises silicon oxide (SiO), from damage during the following etching process due to the different etching rates between SiN and SiO. After forming the SiN hard mask layer 120, a photoresist layer 122 is formed thereon.

Please refer to FIGS. 2-3. Next, a photolithography process is performed to pattern the photoresist layer 122 and the SiN hard mask layer 120. As shown in FIG. 2, after removing the photoresist layer 122, the patterned SiN hard mask layer 120 and the spacer 114 are serving as an etching mask in an etching process for forming recesses 130 in the substrate 100 at two sides of the gate 110. After forming the recesses 130, a SEG process is performed to form epitaxial SiGe layers 140 filling the recesses 130 as shown in FIG. 3. Conventionally, an ion implantation can be performed before forming the recesses 130 or after the SEG process to form a recessed source/drain.

With the progress of device miniaturization and the shrink of critical dimension (CD), it is found that the photoresist layer 122 formed on the SiN hard mask layer 120 easily collapses due to the inferior adhesion of the photoresist layer 122 to the SiN hard mask layer 120. It is well-known that poor adhesion brings about severe undercutting, loss of resolution, or possibly the complete loss of the pattern. And the collapsed photoresist layer 122 not only adversely affects the pattern transferring results, but also adversely affects the etching results. As a countermeasure against to the problem, there has been developed an oxygen (O₂) treatment for modifying the SiN hard mask layer 120. Consequently, it is found that the adhesion between the SiN hard mask layer 120 and the photoresist layer 122 is improved.

However, there is a trade-off problem resulted from introduction of the O₂ treatment: the O₂ treatment improves the adhesion of the photoresist layer 122 to the SiN hard mask layer 120 by transforming a surface of the SiN hard mask layer 120 into a Si-rich surface. Silicon is a material to which photoresist layer 122 will more readily adhere than SiN. But the Si-rich surface of the SiN hard mask layer 120 serves as a seed layer in the SEG process and thus numberless tiny fall-on defects comprising SiGe are ubiquitously formed on the SiN hard mask layer 120. Those fall-on defects having diameter of 30-60 nanometers (nm) make the SiN hard mask layer a haze surface. Furthermore, since the fall-on defects comprise SiGe, it affects the etching rate of the SiN hard mask layer 120. During the etching process used to remove the SiN hard mask layer 120, it is difficult to remove the SiN hard mask layer 120 due to the haze surface, which comprise SiGe, and easy to damage the SiGe layers 140.

Therefore, there is a continuing need in the semiconductor processing art to develop a method that is able to solve the above mentioned trade-off problem.

### SUMMARY OF THE INVENTION

According to a first aspect of the present invention, there is provided a semiconductor processing method comprising providing a substrate, forming a hard mask layer on the substrate, performing a wet treatment to a surface of the hard mask layer, and forming a photoresist on the hard mask layer after the wet treatment.

According to a second aspect of the present invention, there is provided a method of manufacturing MOS transistor comprising steps of: providing a substrate having a gate formed thereon; forming a hard mask layer on the substrate; performing an acid treatment to a surface of the hard mask layer; forming a photoresist layer on the hard mask layer after the acid treatment; performing a photolithography process to pattern the photoresist layer and the hard mask layer; performing an etching process to form recesses in the substrate; and performing a selective epitaxial growth (SEG) method to form epitaxial layers respectively filling the recesses.

According to the provided methods, the wet treatment and the acid treatment are performed to improve the adhesion between the hard mask layer and the photoresist layer, therefore collapse of the photoresist is avoided. Furthermore, no epitaxial layer will be formed on the surface of the hard mask layer because the adhesion is improved without forming the Si-rich surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic drawings illustrating a conventional method for manufacturing MOS transistor utilizing SEG method;

FIGS. 4-8 are schematic drawings illustrating a method of manufacturing MOS transistor provided by a preferred embodiment of the present invention; and

FIG. 9 is a drawing illustrating a modification of method provided by the preferred embodiment.

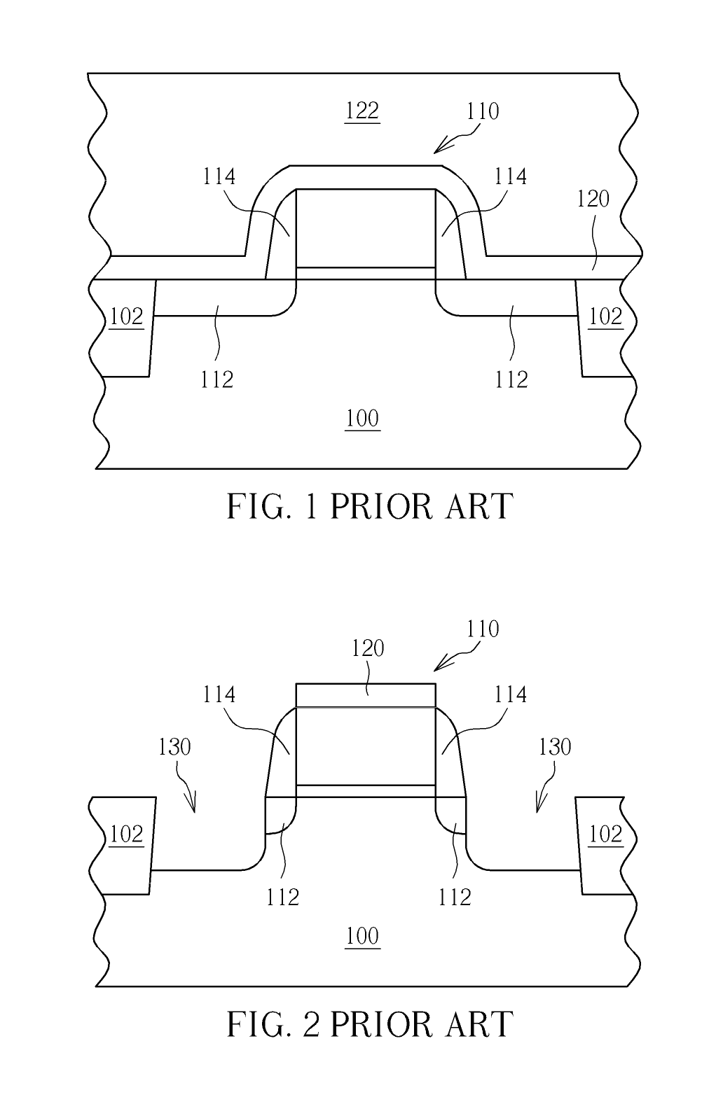

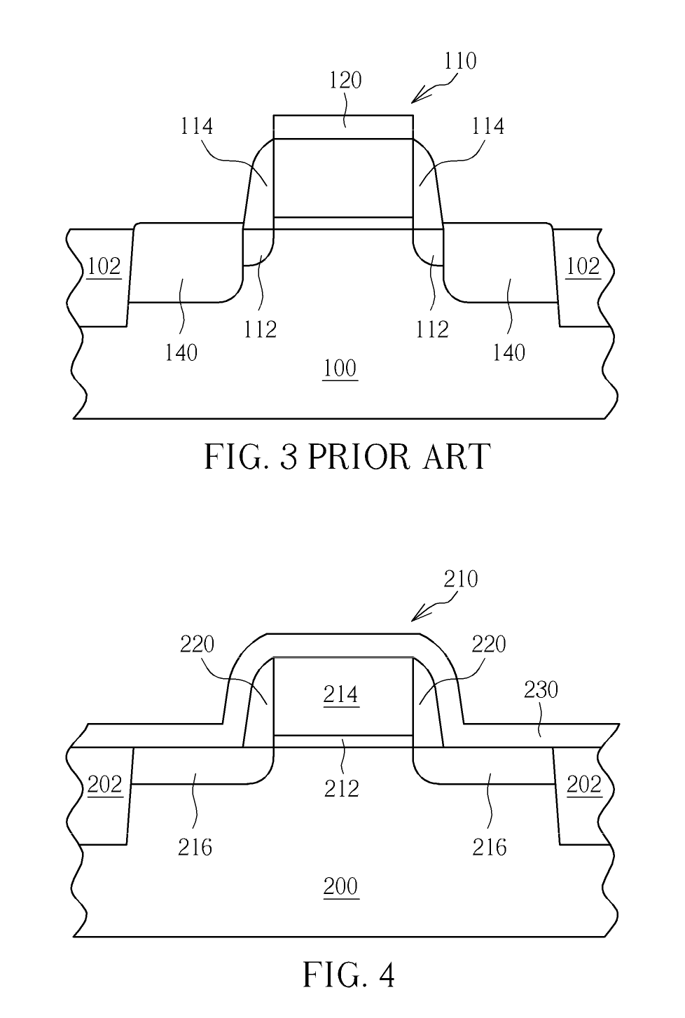

### DETAILED DESCRIPTION

Please refer to FIGS. 4-8, which are schematic drawings illustrating a method of manufacturing MOS transistor provided by a preferred embodiment of the present invention. As shown in FIG. 4, a substrate 200 such as a silicon substrate or a silicon-on-insulator (SOI) substrate is provided. And at least a gate 210 and shallow trench isolations (STIs) 202 providing electrical isolation are formed on the substrate 200. The gate 210 comprises a gate dielectric layer 212 and a gate conductive layer 214 formed thereon. Then, a first ion implantation is performed to form lightly doped drains (LDDs) 216 in the substrate 200 respectively at two sides of the gate 210, and followed by forming a spacer 220 on a sidewall of the gate 210.

Please still refer to FIG. 4. Next, a hard mask layer 230 is formed on the gate 210. The hard mask layer 230 may include silicon nitride (SiN), silicon oxynitride (SiON), silicon carbon nitride (SiCN), titanium nitride (TiN), silicon carbide (SiC), and/or other materials. Preferably, the hard mask layer 230 is a SiN layer that has an etching rate different from silicon oxide (SiO), by which the STI 202 is filled. Thus, the STI 202 is prevented from damage during the following etching process. The hard mask layer 230 can be deposited by chemical vapor deposition (CVD), low pressure chemical vapor deposition (LPCVD), plasma-enhanced chemical vapor deposition (PECVD), sub-atmosphere chemical vapor deposition (SACVD), atomic layer deposition (ALD), physical vapor deposition (PVD), and/or other appropriate processing techniques.

Please refer to FIG. 5. Then, a wet treatment 240, preferably an acid treatment 240, is performed to a surface of the hard mask layer 230. The acid treatment 240 comprising sulfuric acid (HₛSO₄) can be performed exemplarily by a sulfuric acid/hydrogen peroxide/deionized water mixture (SPM) method. Accordingly, Si—N bonds of the surface of the hard mask layer 230 are decreased while Si—O bonds are increased. Thus an oxidized surface 232 is formed on the hard mask layer 230 after the acid treatment 240. The oxidized surface 232 is preferably kept very thin. Thus, a heterogeneous hard mask layer having the SiN hard mask layer 230 and the oxidized surface 232 is obtained.

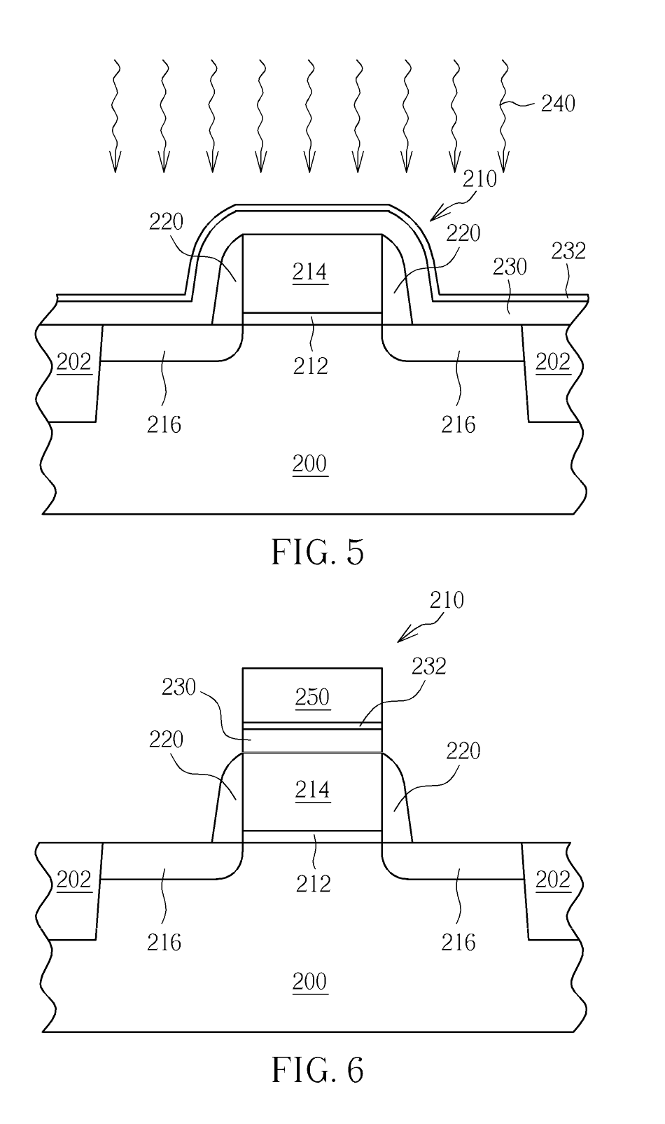

Please refer to FIG. 6. A photoresist layer 250 is formed on the oxidized surface 232 of the hard mask layer 230 after performing the acid treatment 240. Then, a photolithography process is performed to pattern the photoresist layer 250 and the hard mask layer 230. As shown in FIG. 6. The patterned photoresist layer 250 and the hard mask layer 230 cover the gate 210 while the substrate 200 and the spacer 220 are exposed.

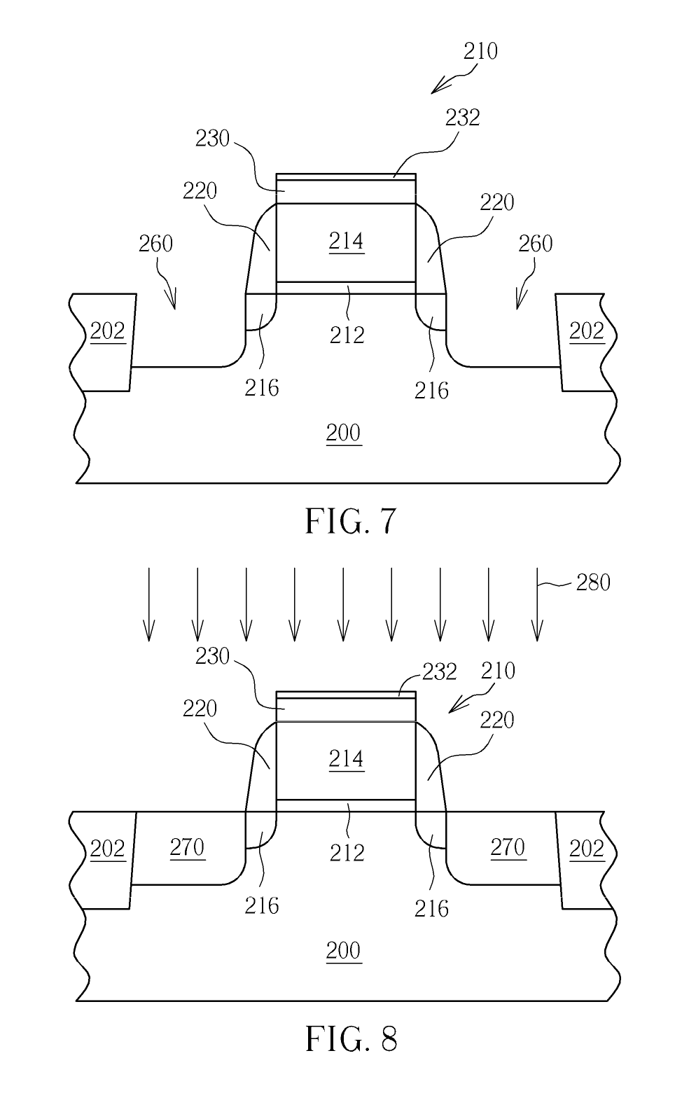

Please refer to FIG. 7. After removing the patterned photoresist layer 250, the patterned hard mask layer 230 and the spacer 220 are used to be an etching mask. And an etching process is performed to form recesses 260 in the substrate 200 at two sides of the gate 210.

Please refer to FIG. 8. After forming the recesses 260, a cleaning process used to remove native oxides and other impurities is performed. Then, a selective epitaxial growth (SEG) method is performed to form epitaxial layers 270 respectively in the recesses 260. Additionally, a second ion implantation 280 is performed after performing the SEG process, thus the recesses 260 filled with the epitaxial layer 270 are to serve as source/drain. However, those skilled in the art would easily realize that the second ion implantation 280 is not limited to be performed before etching the recesses 260. When the gate 210 is a gate of a PMOS transistor, the epitaxial layer 270 comprises silicon germanium (SiGe); when the gate 210 is a gate of an NMOS transistor, the epitaxial layer 270 comprises silicon carbide (SiC).

According to the method provided by the preferred embodiment, the wet treatment/acid treatment 240 is performed to improve the adhesion between the hard mask layer 230 and the photoresist layer 250 by forming the thin oxidized surface 232. It is well-known the adhesion between the photoresist and SiO are better than that between photoresist and SiN. Therefore the patterned photoresist layer 250 is prevented from collapse even though critical dimension of the process keeps on shrinking. Furthermore, due to the existence of the oxidized surface 232, no epitaxial layer is to be formed on the hard mask layer 230. And thus the hard mask layer 230 can be easily removed without damaging the gate 210 and the epitaxial layers 270.

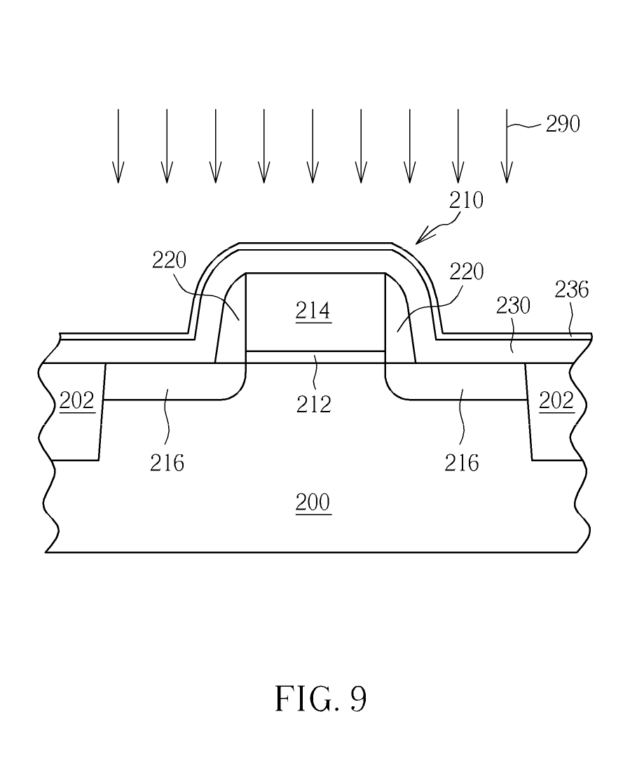

Furthermore, the oxidized surface 232 of the hard mask layer 230 can be formed not only by performing the abovementioned acid treatment, but also formed by performing a deposition process. Please refer to FIG. 9, which is a drawing illustrating a modification of the method provided by the preferred embodiment. As shown in FIG. 9, after forming the hard mask layer 230 preferably having SiN, a deposition process 290 is performed to form a thin oxidized layer 236 on the hard mask layer 230. The deposition process 290 for forming the oxidized layer 236 and the deposition process for forming the hard mask layer 230 can be in-situ or ex-situ performed. Accordingly, the oxidized layer 236 formed on the hard mask layer 230 serves as its oxidized surface. Thereafter, following processes such as forming and patterning the photoresist layer 250, the etching process to form the recesses 260, and the SEG method to form the epitaxial layers 270 filling the recesses 260 are sequentially performed as mentioned above.

As mentioned above, adhesion between the heterogeneous hard mask layer and the photoresist layer 250 is improved by forming the thin oxidized layer 236 by the deposition process 290. Therefore the patterned photoresist layer 250 is prevented from collapse even though critical dimension of the process keeps on shrinking. Furthermore, due to the existence of the oxidized layer 236, no epitaxial layer is to be formed on the hard mask layer 230. And thus the hard mask layer 230 can be easily removed without damaging the gate 210 and the epitaxial layers 270.

According to the method provided by the present invention, the oxidized surface formed by the acid treatment or the deposition is formed to improve the adhesion between the hard mask layer and the photoresist layer by forming the oxidized surface, therefore collapse of the photoresist is avoided. Furthermore, no epitaxial layer is formed on the surface of the hard mask layer because the adhesion is improved by forming the oxidized surface, not the Si-rich surface. In addition, the method for manufacturing MOS transistor with a heterogeneous hard mask is not limited to form the recessed source/drain, it also applies to form a raised source/drain or a planer source/drain.

Those skilled in the art will readily observe that numerous modifications and alterations of the device and method may be made while retaining the teachings of the invention.

What is claimed is:

1. A semiconductor processing method comprising:
providing a substrate;
forming a hard mask layer on the substrate;
performing a wet treatment to a surface of the hard mask layer; and
forming a photoresist on the hard mask layer after the wet treatment.

2. The method of claim 1, wherein the substrate further comprises at least a semiconductor device formed therein.

3. The method of claim 1, wherein the hard mask layer comprises silicon nitride (SiN).

4. The method of claim 1, wherein the wet treatment comprises a sulfuric acid (HₛSO₄).

5. The method of claim 4, wherein the wet treatment comprises a sulfuric acid/hydrogen peroxide/deionized water mixture (SPM) method.

6. A method of manufacturing metal-oxide-semiconductor (MOS) transistor comprising steps of:
providing a substrate having a gate formed thereon;
forming a hard mask layer on the substrate;
performing an acid treatment to a surface of the hard mask layer;
forming a photoresist layer on the hard mask layer after performing the acid treatment;
performing a photolithography process to pattern the photoresist layer and the hard mask layer;
performing an etching process to form recesses in the substrate; and
performing a selective epitaxial growth (SEG) method to form epitaxial layers respectively in the recesses.

7. The method of claim 6 further comprising steps performed before forming the hard mask layer:
performing a first ion implantation to form lightly doped drains (LDDs) in the substrate respectively at two sides of the gate; and
forming a spacer on a sidewall of the gate.

8. The method of claim 7 further comprising a step of performing a second ion implantation to form a source/drain at two sides of the gate.

9. The method of claim 6, wherein the acid treatment comprises a wet treatment.

10. The method of claim 6, wherein the hard mask layer comprises silicon nitride (SiN).

11. The method of claim 10, wherein the acid treatment comprises sulfuric acid (HₛSO₄).

12. The method of claim 11, wherein the acid treatment further comprises hydrogen peroxide (H₂O₂) and deionized water.

13. The method of claim 6, wherein the epitaxial layers comprise silicon germanium (SiGe) or silicon carbide (SiC).
